(19) United States
(12) Patent Application Publication
(10) Pub. No.: US 2019/0089346 A1
(43) Pub. Date: Mar. 21, 2019

(54) CONTROL CIRCUIT, CONTROL METHOD, AND NON-TRANSITORY STORAGE MEDIUM

(71) Applicant: KABUSHIKI KAISHA TOSHIBA, Minato-ku (JP)

(72) Inventor: Shusuke KAWAI, Fujisawa (JP)

(73) Assignee: KABUSHIKI KAISHA TOSHIBA, Minato-ku (JP)

(21) Appl. No.: 15/903,333

(22) Filed: Feb. 23, 2018

(30) Foreign Application Priority Data
Sep. 19, 2017 (JP) 2017-179439

(51) Int. Cl. H03K 17/16; H03K 17/284

(52) U.S. Cl. CPC H03K 17/161; H03K 17/284

(57) ABSTRACT

A control circuit, which is one aspect of the present invention, controls a gate signal input to a semiconductor switching element. The control circuit includes a load signal measuring device, a gate signal generator, and a timing adjuster. The load signal measuring device measures a load signal of the semiconductor switching element. The gate signal generator generates the gate signal on the basis of the load signal. The timing adjuster adjusts a timing of when the gate signal is input to the semiconductor switching element on the basis of a history of the load signal.

### CROSS-REFERENCE TO RELATED APPLICATION (S)

This application is based upon and claims the benefit of priority from Japanese Patent Application No. 2017-179439, filed Sep. 19, 2017; the entire contents of which are incorporated herein by reference.

### FIELD

An embodiment relates to a control circuit, a control method, and a non-transitory storage medium.

### BACKGROUND

In switching of a semiconductor switching element, use of a gate signal at a high-frequency of about 100 kHz may cause electro-magnetic interference (EMI), which may affect a circuit including the semiconductor switching element and other circuits. A way of suppressing such EMI is to control, on the basis of the drain voltage of the semiconductor switching element, the gate signal which is in correlation with the drain voltage and the like. For example, such a fluctuation in the gate signal that the differential value of the drain voltage stays around a target value is learned, and the gate signal is controlled on the basis of learning, so that an increase in EMI can be suppressed.

However, it has been found that, when rising or falling speed of switching is set higher to increase power efficiency, the differential value of the drain voltage largely exceeds the target value even if the gate signal is controlled as learned, and EMI cannot be suppressed.

### BRIEF DESCRIPTION OF THE DRAWINGS

FIG. 1 is a block diagram illustrating an example of a circuit including a control circuit according to one embodiment of the present invention;

FIG. 2 is a diagram for explaining an optimum differential signal;

FIG. 3 is a diagram illustrating optimum differential signals given by a control circuit according to one embodiment of the present invention; and

FIG. 4 is an example flow chart of optimum gate signal generating processing in a control circuit according to one embodiment of the present invention.

### DETAILED DESCRIPTION

One embodiment of the present invention suppresses EMI while increasing power efficiency, by adjusting the input timing of gate signal input to a semiconductor switching element.

A control circuit, which is one aspect of the present invention, controls a gate signal input to a semiconductor switching element. The control circuit includes a load signal measuring device, a gate signal generator, and a timing adjuster. The load signal measuring device measures a load signal of the semiconductor switching element. The gate signal generator generates the gate signal on the basis of the load signal. The timing adjuster adjusts a timing of when the gate signal is input to the semiconductor switching element on the basis of a history of the load signal.

An embodiment will be explained in detail below with reference to the accompanying drawings. The present invention is not limited to the embodiment.

### One Embodiment of the Present Invention

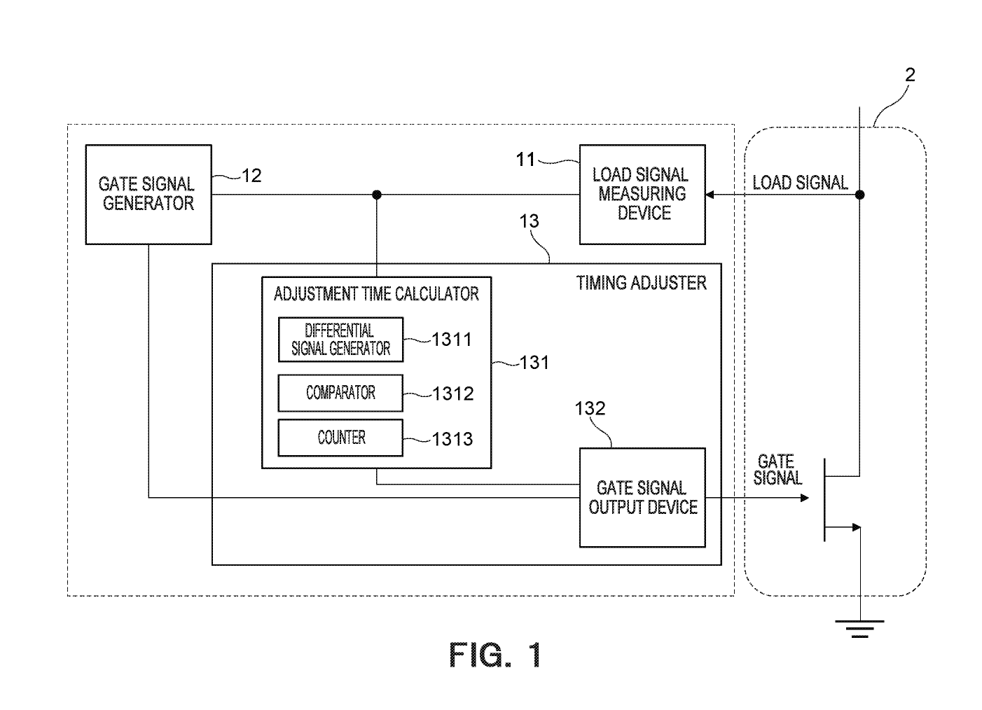

FIG. 1 is a block diagram illustrating an example of a circuit including a control circuit according to one embodiment of the present invention. a control circuit 1 and a semiconductor switching element 2 according to one embodiment of the present invention are shown. The control circuit 1 includes a load signal measuring device 11, a gate signal generator 12, and a timing adjuster 13. The timing adjuster 13 includes an adjustment time calculator 131 and a gate signal output device 132. The adjustment time calculator 131 includes a differential signal generator 1311, a comparator 1312, and a counter 1313.

The control circuit 1 controls the gate signal input to the semiconductor switching element 2, thereby controlling the load signal of the semiconductor switching element 2. To be specific, the control circuit 1 controls the differential signal related to the load signal of the semiconductor switching element 2 such that it does not exceed a limit value. EMI by the semiconductor switching element 2 increases in accordance with a steep change of the load signal, i.e., the amplitude of the differential signal, so that the above-described control by the control circuit 1 can suppress EMI.

Incidentally, the control circuit 1 shown in FIG. 1 is merely illustrative. The number, arrangement, and the like of components may be changed in accordance with the performance required for the control circuit 1, as long as the gate signal can be controlled in the same manner as with the configuration shown in FIG. 1. For example, the differential signal generator 1311, which is in the adjustment time calculator 131 of the timing adjuster 13 in FIG. 1, may also be provided in the load signal measuring device 11 and the gate signal generator. Further, it is possible that the load signal measuring device 11 and the gate signal generator 12 include the differential signal generators 1311 respectively, and the timing adjuster 13 does not include the differential signal generator 1311. In addition, there may be a component(s) not shown in the drawing.

The semiconductor switching element 2 is a semiconductor element that is turned on and off depending on the gate signal. For example, a metal-oxide-semiconductor field-effect transistor (MOSFET), an insulated gate bipolar transistor (IGBT), or a thyristor can be used as the semiconductor switching element 2. In addition, a compound semiconductor, such as silicon carbide (SiC) or gallium nitride (GaN), can be used.

The load signal of the semiconductor switching element 2 may be a voltage between the drain and source of the semiconductor switching element 2, a current flowing into the semiconductor switching element 2, or a combination thereof.

The internal configuration of the control circuit 1 will now be described. The load signal measuring device 11 is connected to the semiconductor switching element 2 and measures the load signal of the semiconductor switching element 2. The measurement results related to the load signal are transmitted to the gate signal generator 12 and the timing adjuster 13.

Incidentally, the load signal measuring device 11 may perform preprocessing for processing in the gate signal generator 12 and the timing adjuster 13. For example, the load signal measuring device 11 may include an AD converter and perform analog to digital conversion on the load signal thereby. Further, the load signal measuring device 11 may include a differentiator to generate a differential signal from the load signal. When the load signal measuring device 11 generates the differential signal, the load signal measuring device 11 can be referred to as a differential signal generator. In addition, the load signal measuring device 11 may adjust the amplitudes of the load signal and the differential signal.

The gate signal generator 12 generates a gate signal to the semiconductor switching element 2 on the basis of the load signal measured by the load signal measuring device 11. To be specific, the gate signal generator 12 generates the following gate signal on the basis of the differential signal of the load signal that appears during the period in which the previous gate signal is input, such that the differential signal of the load signal that appears during the period in which the following gate signal is input does not exceed a limit value. Repetition of this gate signal generating processing allows the gate signal generator 12 to learn an appropriate gate signal.

A learning scheme for the gate signal generator 12 may be a well-known scheme. An example is described below. Multiple profiles for generating a gate signal may be stored in advance. The multiple profiles may be varied according to a previously measured load signal. The varied multiple profiles may be summed, thereby generating the following gate signal. In addition, the differential signal of a load signal may be generated in the gate signal generator 12 or a differential signal generated in the load signal measuring device 11 may be obtained.

After the termination of learning, the gate signal generator 12 generates a gate signal which is determined as being optimum. Incidentally, a gate signal which is determined as being optimum will be hereinafter denoted as an optimum gate signal. A load signal measured upon input of an optimum gate signal will be hereinafter denoted as an optimum load signal. An optimum differential signal of a load signal will be hereinafter denoted as an optimum differential signal. Incidentally, they should not necessarily be optimum in practical cases.

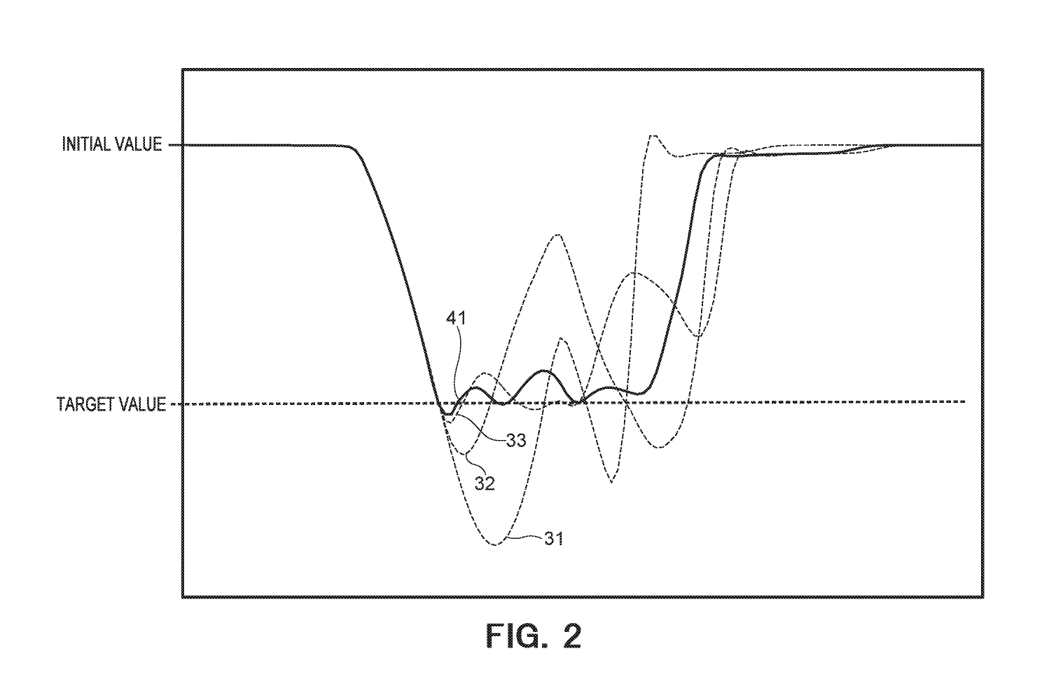

FIG. 2 is a diagram for explaining an optimum differential signal. The graph 41 of the optimum differential signal is indicated by a black solid line. The graphs 31 to 33 of differential signals observed when gate signals during learning are input are indicated by dotted lines. Incidentally, the larger the number of the reference numeral of a differential signal graph, the larger the number of times of learning. As shown in FIG. 2, if the gate signal gradually approaches the optimum gate signal after repeated learning, the differential signal gradually converges to the optimum differential signal.

A straight dotted line of a constant value indicates a target value of the optimum differential signal. The target value of the optimum differential signal is predetermined according to desired power efficiency and EMI. As shown in the example shown in FIG. 2, the optimum differential signal decreases from the initial value toward the target value and eventually reaches the target value. After reaching the target value, the optimum differential signal stays around the target value, and then rises back to the initial value.

During the period in which the optimum differential signal drops from the initial value to the target value and then rises from the target value to the initial value shown in FIG. 2, EMI can fall within a desired value as long as it is in an allowable range around the target value. However, for example, if the rising (or falling) speed upon switching is about 0.1 μsec, the optimum differential signal does not stop around the target value at the first drop and passes through the limit value of the allowable range (here, lower limit value). Afterwards, it passes through the lower limit value and rises back in the allowable range. Accordingly, if the switching speed is about several tens of micro seconds, the optimum differential signal may go out of the allowable range, so that EMI cannot be kept within a desired value. In other words, when the switching speed is increased to improve power efficiency, there is the risk that the optimum differential signal does not fall within the allowable range.

In view of this, in the control circuit 1 of this embodiment, to prevent the optimum differential signal from going out of the allowable range, the timing adjuster 13 adjusts the input timing of the gate signal. To be specific, the timing adjuster 13 sets the input timing prior to a predetermined timing in accordance with the adjustment time which calculated on the basis of a load signal history. If the rising (or falling) speed upon switching is about several tens of micro seconds, the rise (or fall) time of the optimum differential signal is about 0.1 μsec. In other words, when the rising (or falling) speed upon switching is high, the drop of the optimum differential signal is steep, and the optimum differential signal probably reaches the limit value before the appearance of an influence of a change of the gate signal on the optimum differential signal.

The load signal history refers to multiple load signals measured by the load signal measuring device 11 every gate signal input period. For example, the n-th load signal measured during the input period (first input period) of the n-th (n is an integer of one or more) gate signal during learning and the m-th load signal measured during the input period (second input period) of the m-th (m is an integer of one or more different from n) gate signal are registered in the history. The timing adjuster 13 performs comparison between the n-th differential signal of the load signal and the m-th differential signal of the load signal (the first differential signal and the second differential signal), and calculates adjustment time from the obtained difference. Incidentally, the integers n and m are assumed to be, but not necessarily, adjacent integers.

Incidentally, the load signal history may be stored either in a memory in the load signal measuring device 11, a memory in the timing adjuster 13, or any other memory in the control circuit 1. All the measured load signals are not necessarily left in the history. When comparison between the currently measured differential signal and the previously measured differential signal is performed, the measurement results obtained before the previous measurement should not necessarily be left in the history.

The adjustment time is calculated by the adjustment time calculator 131. To be specific, the differential signal generator 1311 generates differential signals from the respective two load signals registered in the history. The comparator 1312 performs comparison between two differential signals to calculate a first time point (the point in time at which a difference between the two differential signals occurs). Subsequently, the counter 1313 counts the time from a second time point (the point at which two differential signals moved from the initial value to the target value) to the point at which a difference between the two differential signals occurred. The counted time corresponds to the adjustment time. Incidentally, when the values of two differential signals are apart from predetermined values, it can be determined that there is a difference.

Incidentally, the adjustment time calculator 131 may obtain differential signals from the load signal measuring device 11 or the gate signal generator 12. If differential signals can be obtained from another component, the differential signal generator 1311 may be omitted.

The gate signal output device 132 inputs a gate signal to the semiconductor switching element 2 before the predetermined timing, in accordance with the calculated adjustment time. The time to the predetermined timing may be equal to the adjustment time or the time calculated using a predetermined expression on the basis of the adjustment time.

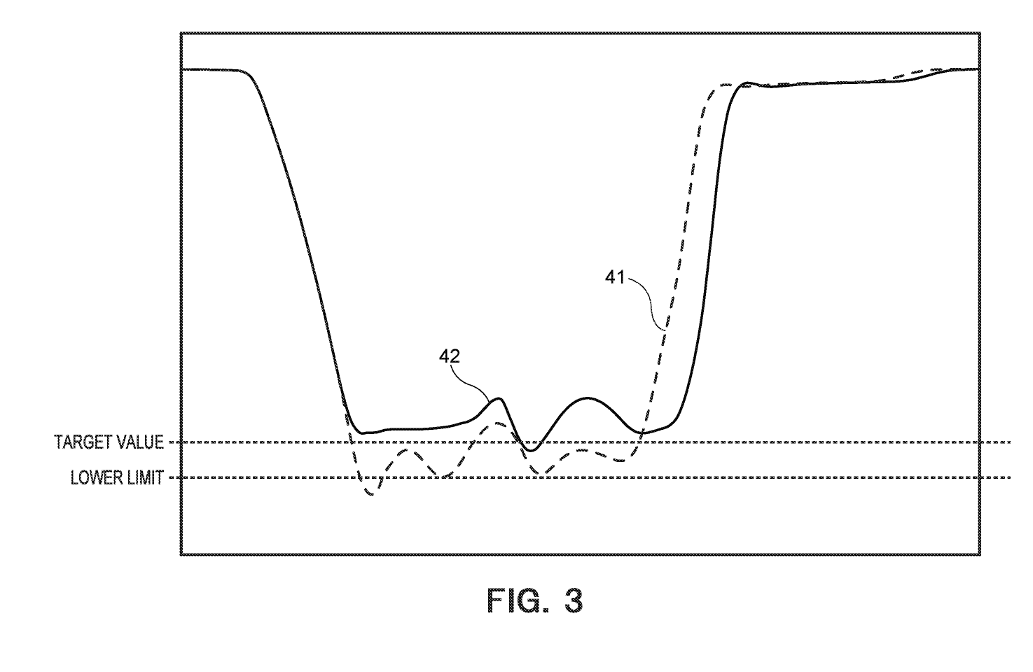

FIG. 3 is a diagram illustrating optimum differential signals given by a control circuit according to one embodiment of the present invention. A graph 42 indicated by a solid line shows an optimum differential signal given by a control circuit according to one embodiment of the present invention. In other words, the graph 42 indicated by the solid line shows an optimum differential signal obtained when the gate signal input timing is adjusted. A graph 41 indicated by a dotted line shows an optimum differential signal obtained when the gate signal input timing shown in FIG. 2 is not adjusted. As shown in FIG. 3, the optimum differential signal indicated by the solid line decreases from the initial value toward the target value but the drop stops before the target value. Thus, the control circuit of this embodiment prevents optimum differential signals from going out of the allowable range.

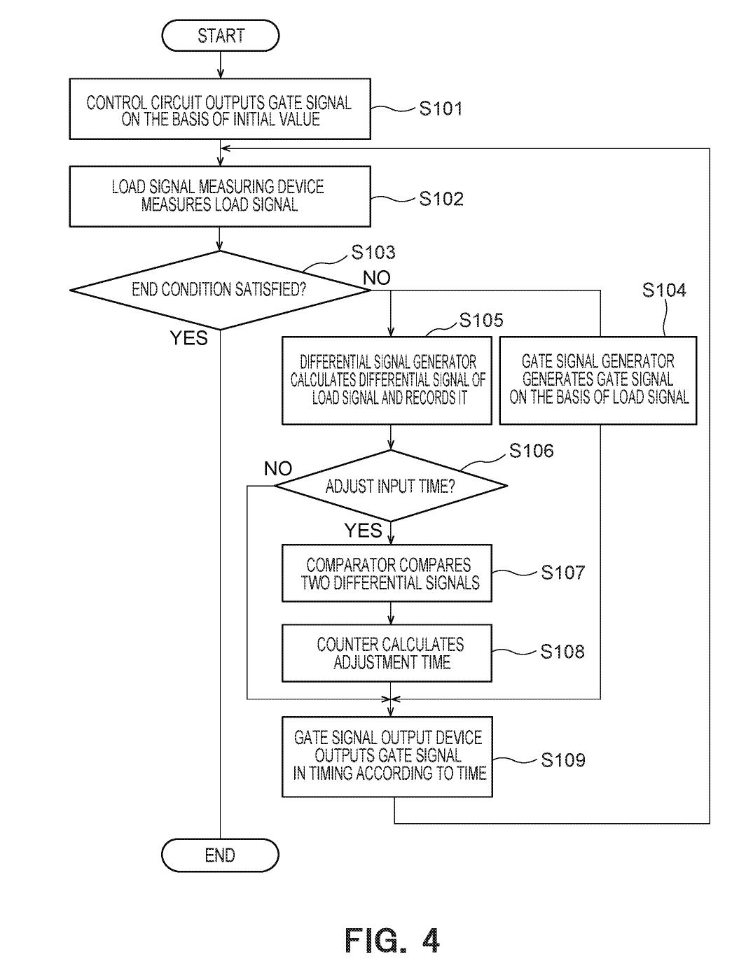

Processing in each component in the control circuit 1 will now be explained. FIG. 4 is an example flow chart of optimum gate signal generating processing in a control circuit according to one embodiment of the present invention.

First, the control circuit 1 outputs a gate signal on the basis of the initial value (S101). To be specific, the gate signal generator 12 generates the gate signal on the basis of the initial value, the adjustment time calculator 131 does not calculate the adjustment time, and the gate signal output device 132 outputs the gate signal in a predetermined timing. Meanwhile, the load signal measuring device 11 calculates the load signal (S102). Incidentally, processing of S101 and S102 is performed in the same period.

If a predetermined end condition is satisfied (YES in S103), this flow ends. The end condition may be that the differential signal of the load signal is within the allowable range. In this case, the optimum gate signal is output after the end of the flow. Alternatively, the end condition may be that the number of times of generation of gate signal exceeds a threshold. The end condition may be determined by any component in the control circuit 1.

If the end condition is not satisfied (NO in S103), processing in the gate signal generator 12 and processing in the timing adjuster 13 are performed concurrently. The gate signal generator 12 generates a gate signal on the basis of the load signal (S104). The generated gate signal is transmitted to the timing adjuster 13.

Meanwhile, in the timing adjuster 13, the differential signal generator 1311 calculates the differential signal of the load signal and records it (S105). Subsequently, whether the input time is adjusted is determined (S106). Whether the input time is adjusted may be determined concerning the load signal value, the amount of change of load signal, or the like. For example, if it is determined that there is substantially no difference between the previously measured load signal and the currently measured load signal, the input time may be adjusted. Alternatively, if the number of times of learning is larger than a predetermined number, the input time may be adjusted. Alternatively, if two or more differential signals are recorded, the input time may be regularly adjusted.

Under the current circumstances, only one differential signal is recorded and the input time cannot be adjusted (NO in S106), so that the gate signal output device 132 receiving the gate signal from the gate signal generator 12 outputs the gate signal in the timing according to the adjustment time (S109). Under the current circumstances, since the counter 1313 has not calculated the adjustment time yet, the adjustment time is the initial value. In particular, the gate signal is output in a predetermined timing. Afterwards, the load signal measuring device 11 calculates the load signal again (S102).

If the end condition is not satisfied again (NO in S103), the differential signal generator records the differential signal obtained by the current measurement, so that previous and current differential signals are included in the history. Subsequently, when the input time is adjusted (YES in S106), the comparator 1312 performs comparison between two differential signals recorded in the history and calculates the point at which a difference between the two differential signals occurred (S107).

Subsequently, the counter 1313 counts a time length and calculates the adjustment time (S108). The time length represents a length from the point at which two differential signals reached the target value to the point at which a difference between the two differential signals occurred. The gate signal output device 132 outputs a gate signal in a timing in accordance with the adjustment time given by the counter 1313 (S109). Afterwards, the load signal measuring device 11 calculates the load signal again (S102).

The above-described processing is repeated until the end condition is satisfied. Consequently, an optimum gate signal is input in an optimum input timing.

As described above, in this embodiment, the input timing of a gate voltage is adjusted according to a measured load signal. Accordingly, even if switching is made in about 0.1 μsec, the differential signal of a load signal is prevented from going out of an allowable range, so that EMI falls within a predetermined value.

Incidentally, the control circuit 1 of this embodiment is assumed to be implemented using a dedicated hardware, such as an integrated circuit (IC), that is mounted with a processor and the like. However, each component of the control circuit 1 may be implemented using a software (program). A control device for the above-described processing in each component can be implemented by, for example, using a general-use computer device as a basic hardware and executing a program stored in a memory in a processor such as a central processing unit (CPU) in the computer device.

The term “memory” subsumes any electronic component that can store electronic information. A “memory” may refer to a random access memory (RAM), a read only memory (ROM), a programmable read only memory (PROM), an erasable programmable read only memory (EPROM), an electrically erasable PROM (EEPROM), a nonvolatile random access memory (NVRAM), a Flash memory, or a magnetic or optical data storage, which are readable by a processor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A control circuit configured to control a gate signal input to a semiconductor switching element, comprising:
a load signal measuring device configured to measure a load signal of the semiconductor switching element;
a gate signal generator configured to generate the gate signal on the basis of the load signal; and
a timing adjuster configured to adjust a timing of when the gate signal is input to the semiconductor switching element on the basis of a history of the load signal.

2. The control circuit according to claim 1, wherein
the timing adjuster sets the timing of when the gate signal is input to the semiconductor switching element prior to a predetermined timing.

3. The control circuit according to claim 2, wherein
the timing adjuster includes:
an adjustment time calculator configured to calculate adjustment time on the basis of a first differential signal related to the load signal appearing during a first input period in which the gate signal is input, and a second differential signal related to the load signal appearing during a second input period in which the gate signal is input; and
a gate signal output device configured to output the gate signal, prior to the predetermined timing, to the semiconductor switching element on the basis of the adjustment time.

4. The control circuit according to claim 3,
wherein the adjustment time calculator includes:
a comparator configured to calculate a first time point at which a difference between the first differential signal and the second differential signal occurred, by comparing the first differential signal with the second differential signal; and
a counter configured to count time length from a second time point at which the first I and second differential signal reached a target value to the first time point,
wherein the adjustment time is the counted time length, and
wherein the gate signal output device outputs the gate signal to the semiconductor switching element, at the time earlier than the predetermined timing by the adjustment time.

5. A control method for controlling a gate signal input to a semiconductor switching element, comprising:
measuring a load signal of the semiconductor switching element;
generating the gate signal on the basis of the load signal; and
adjusting a timing of when the gate signal is input to the semiconductor switching element on the basis of a history of the load signal.

6. A non-transitory storage medium storing a program allowing a computer to execute a control method for controlling a gate signal input to a semiconductor switching element, the program comprising:
measuring a load signal of the semiconductor switching element;
generating the gate signal on the basis of the load signal; and
adjusting a timing of when the gate signal is input to the semiconductor switching element on the basis of a history of the load signal.
